(19) United States
(12) Patent Application Publication
(10) Pub. No.: US 2025/0093770 A1
(43) Pub. Date: Mar. 20, 2025

(54) ILLUMINATION OPTICAL UNIT FOR A MASK INSPECTION SYSTEM

(71) Applicant: Carl Zeiss SMT GmbH, Oberkochen (DE)

(72) Inventors: Sören Schmidt, Jena (DE); Dirk Doering, Erfurt (DE); Michael Gölles, Jena (DE); Thomas Korb, Schwäbisch Gmünd (DE); Ulrich Matejka, Jena (DE)

(21) Appl. No.: 18/967,091

(22) Filed: Dec. 3, 2024

Related U.S. Application Data
(63) Continuation of application No. PCT/EP2023/064651, filed on Jun. 1, 2023.

(30) Foreign Application Priority Data
Jun. 7, 2022 (DE) 102022205767.8
Apr. 21, 2023 (DE) 102023110173.0
Apr. 21, 2023 (DE) 102023110174.9

(51) Int. Cl. G03F 1/84; G01N 21/956

(52) U.S. Cl. CPC G03F 1/84; G01N 21/956; G01N 2021/95676; G01N 2201/0637; G01N 2201/08; G01N 2201/105

(57) ABSTRACT

An illumination optical unit is part of a mask inspection system for use with EUV illumination light. A hollow waveguide serves to guide the illumination light. For the illumination light, the hollow waveguide has an entrance opening in an entrance plane and an exit opening in an exit plane. An input coupling mirror optical unit is disposed upstream of the hollow waveguide in the beam path of the illumination light and has at least one mirror for imaging a source region of an EUV light source into the entrance opening of the hollow waveguide. An output coupling mirror optical unit serves to image the exit opening of the hollow waveguide into an illumination field. This yields an illumination optical unit whose use efficiency for the EUV illumination light has been optimized.

### CROSS-REFERENCE TO RELATED APPLICATIONS

The present patent application is a continuation of and claims benefit under 35 U.S.C. § 120 from PCT Application No. PCT/EP2023/064651, filed on Jun. 1, 2023, which claims priority to German patent applications DE 10 2022 205 767.8, filed on Jun. 7, 2022, DE 10 2023 110 173.0, filed on Apr. 21, 2023, and DE 10 2023 110 174.9, filed on Apr. 21, 2023. The entire contents of the above applications are incorporated herein by reference.

### TECHNICAL FIELD

The invention relates to an illumination optical unit for a mask inspection system for use with EUV illumination light. Further, the invention relates to an optical system having such an illumination optical unit, and to a mask inspection system having such an illumination optical unit.

### BACKGROUND

Such a mask inspection system is known from U.S. Pat. No. 10,042,248 B2, from DE 102 20 815 A1 and from WO 2012/101269 A1.

### SUMMARY

It is an aspect of the present invention to develop an illumination optical unit for such an inspection system so that its use efficiency for the EUV illumination light is optimized.

According to the invention, this aspect is achieved by an illumination optical unit comprising the features specified in claim 1.

According to the invention, it was recognized that an input coupling mirror optical unit for imaging an EUV light source, with which the illumination optical unit interacts, into the entrance opening of the hollow waveguide provides a high input coupling efficiency. An optical unit as known from U.S. Pat. No. 10,042,248 B2 can be used as an output coupling mirror optical unit.

The input coupling mirror optical unit may comprise at least one mirror for grazing incidence (GI), which is embodied for an angle of incidence of the illumination light of greater than 45°. Alternatively or in addition, the input coupling mirror optical unit may comprise at least one mirror for normal incidence (NI), which is embodied for an angle of incidence of the illumination light of less than 45° and in particular of less than 30°.

The input coupling mirror optical unit may comprise exactly one mirror or else comprise a plurality of mirrors, for example two mirrors.

The arrangement of the input coupling mirror optical unit can be such that a geometric centroid ray of rays of an illumination light beam enters into the entrance plane of the entrance opening at an angle to the normal of the said entrance plane which is less than 2°, less than 1.5°, less than 1° and possibly is of the order of 0.5°. In particular, the geometric centroid ray may enter the entrance opening of the hollow waveguide in a manner perpendicular to the entrance plane. Alternatively, the angle conditions explained above may apply to a chief ray of the illumination light beam. The geometric centroid ray on the one hand and the chief ray on the other hand may not coincide, especially if a pupil of the illumination optical unit is not illuminated homogenously and/or not illuminated symmetrically.

Depending on the angle of incidence and/or the position, with respect to reflective internal walls of the hollow waveguide, of a plane of incidence of an incident chief ray of the beam of the illumination light or incident geometric centroid ray of marginal rays of the beam of the illumination light, this may result in a monopole-like, dipole-like or multi-pole-like, for example quadrupole-like, illumination angle distribution of the illumination field.

The mirrors of the illumination optical unit, which is to say the input coupling mirror optical unit and/or output coupling mirror optical unit in particular, may contain free-form reflection surfaces.

An embodiment of the input coupling mirror optical unit according to claim 2 as ellipsoid mirror enables an input coupling mirror optical unit with exactly one reflection between the source region of the light source and the entrance opening of the hollow waveguide, allowing a high EUV throughput of the input coupling mirror optical unit.

An adjustability of the entrance angle according to claim 3 enables an embodiment of the illumination optical unit which allows setting of a defined illumination angle distribution for illuminating the illumination field. Depending on the choice of the entrance angle of the illumination light beam with respect to the entrance plane of the entrance opening, it is possible to obtain, for example, a monopole-like, a dipole-like or a multi-pole-like, for example a quadrupole-like, illumination angle distribution of the illumination field.

Angles of incidence according to claim 4 enable a high overall transmission of the input coupling mirror optical unit. Alternatively or in addition, the angle of incidence may also be less than 45° and, for example, range between 0° and 45°, for example range between 0° and 30°.

An input coupling mirror optical unit according to claim 5 enables precise imaging of the source region of the EUV light source into the entrance opening with a precisely specifiable imaging factor. The input coupling mirror optical unit can be embodied as a Wolter-type mirror optical unit, in particular as a Wolter Type I mirror optical unit. A combination of a hyperboloid mirror and a paraboloid mirror for the input coupling mirror optical unit is also possible. It is possible to use design principles as described in U.S. Pat. No. 10,042,248 B2, for example. Alternatively or in addition, use can be made of mirrors with free-form reflection surfaces.

A rectangular entrance opening according to claim 6 was found to be particularly suitable for specifying defined illumination conditions and is able to be manufactured precisely. The entrance opening can also have a square embodiment. An edge length of bounding edges of the entrance opening can be less than 2 mm and can be less than 1 mm, in particular. A ratio of a length of the hollow waveguide and a typical diameter, for example a rectangle edge length, of the entrance opening can be greater than 10, can be greater than 30, can range between 40 and 80, can be greater than 100, can be greater than 200 and can range between 200 and 300. Such a length/diameter ratio is regularly less than 1000.

A pivotable embodiment of an illumination optical unit component according to claim 7 facilitates an adjustment of the illumination optical unit, in particular for the purpose of specifying an illumination angle distribution, which is to say an illumination setting of the illumination optical unit. By way of an appropriately embodied actuator system, the at least one component of the illumination optical unit embodied to be pivotable about at least one pivot axis can be displaced in relation to more than one rotational and/or translational degree of freedom, for example in relation to 2, 3, 4, 5 or 6 degrees of freedom.

The pivotable illumination optical unit component may be the hollow waveguide. A pivot axis of the hollow waveguide may be located in the entrance plane of the entrance opening. A pivot adjustment of the hollow waveguide can be used for an étendue optimization of the illumination optical unit.

For example, the term étendue is explained in the book “Non-imaging Optics” by Benitez, P. G., Minano, J. C., Winston, R., Narkis Shatz and John C. Bortz, W. c. b. (2005). An étendue optimization can be carried out in such a way that the étendue upon exit from the hollow waveguide is as low as possible, which is to say that, especially in pupil coordinates, an angle diameter of an illumination light beam exiting from the hollow waveguide remains as small as possible in relation to an exit normal.

A possible displaceability of the hollow waveguide in relation to a plurality of degrees of freedom by use of the actuator system can be used for setting the translation and/or rotation or pivot position of the hollow waveguide within the illumination optical unit.

A number of reflections for all individual rays of the illumination light within the hollow waveguide may be less than a maximum upper limit. This upper limit for the number of reflections may be 50. Other numbers of reflections are also possible. A change between different illumination angle distributions by way of small changes in the angle of incidence of the illumination light beam at the entrance opening of the hollow waveguide can be enabled by way of the number of reflections. Moreover, such an embodiment can be implemented in étendue-optimized fashion.

The advantages of an optical system according to claim 9 correspond to those which have already been explained above with reference to the illumination optical unit.

The pivotability of the light source according to claim 10 enables a specification of an illumination angle, in particular an entrance illumination angle of the illumination light beam at the entrance opening of the hollow waveguide. This also allows, firstly, specification of an illumination angle distribution and/or implementation of an étendue optimization.

The advantages of a mask inspection system according to claim 11 correspond to those which have already been explained above with reference to the illumination optical unit and the optical system.

A wafer inspection system can also be constructed correspondingly. The inspection system may comprise an object holder serving to hold the object to be inspected and mechanically coupled to an object displacement drive so that a scanning displacement of the object is possible during the illumination.

The inspection system can be a system for actinic mask inspection.

### BRIEF DESCRIPTION OF DRAWINGS

An exemplary embodiment of the invention is explained in greater detail below with reference to the drawing, in which:

FIG. 1 schematically shows an optical system having an illumination optical unit for a mask inspection system for use with EUV illumination light;

FIG. 2 shows a plan view of the optical system, as seen from the viewing direction II in FIG. 1;

FIG. 3 shows the optical system according to FIG. 1 with a source region of an EUV light source of the optical system which has been pivoted about a pivot axis in comparison with FIG. 1;

FIG. 4 shows a view of the optical system, as seen from the viewing direction IV in FIG. 3;

FIG. 5 schematically shows angle relationships of an illumination light beam upon entrance into an entrance opening of a hollow waveguide of the illumination optical unit, and upon exit from an exit opening of the hollow waveguide;

FIG. 6 shows, schematically and in idealized fashion, reflection conditions in the hollow waveguide in the case of an odd number of internal reflections in the hollow waveguide of an illumination light beam incident at exactly one angle of incidence;

FIG. 7 shows, schematically and in idealized fashion, reflection conditions in the hollow waveguide in the case of a mixture of odd and even numbers of reflections relating to internal reflections in the hollow waveguide of an illumination light beam;

FIG. 8 shows, in a pupil representation, entrance angles of the illumination light beam upon entry into the entrance opening in accordance with FIGS. 6 and 7;

FIG. 9 shows, in an illustration similar to FIG. 8, exit angles of the illumination light beam upon exit from the exit opening in accordance with FIGS. 6 and 7;

FIG. 10 shows, in an illustration similar to FIG. 8, entrance angles upon entrance of the illumination light beam in a configuration, corresponding to FIGS. 6 and 7, for generating a quadrupole illumination of the illumination field;

FIG. 11 shows the exit illumination light angle distribution, which is to say the quadrupole pupil, emerging in the case of the entrance angle conditions according to FIG. 10;

FIG. 12 shows, in an illustration similar to FIGS. 6 and 7, the reflection conditions of the illumination light beam in the case of an even number of reflections in the hollow waveguide;

FIG. 13 shows, in an illustration similar to FIG. 1, a further embodiment of an optical system having an illumination optical unit for a mask inspection system for use with EUV illumination light; and

FIG. 14 shows, in an illustration similar to FIG. 1, a further embodiment of an optical system having an illumination optical unit for a mask inspection system for use with EUV illumination light.

### DETAILED DESCRIPTION

An illumination optical unit 1 is a constituent part of an optical system 2 of a mask inspection system for use with EUV illumination light 3. In the drawing, a beam path of the illumination light 3 is illustrated by way of marginal rays. An illumination field 4 of the mask inspection system is illuminated by way of the illumination light 3.

The illumination light 3 is produced by an EUV light source 5 in a source region or source volume. The light source 5 can produce EUV used radiation in a wavelength range between 2 nm and 30 nm, for example in the range between 2.3 nm and 4.4 nm or in the range between 5 nm and 30 nm, for example at 13.5 nm.

The light source 5 can be embodied as a plasma light source (a high-harmonic EUV source would also be possible). By way of example, this may relate to a laser plasma source (LPP; laser produced plasma) or a discharge source (DPP; discharge produced plasma). In principle, such plasma sources are known light sources for EUV projection exposure apparatuses.

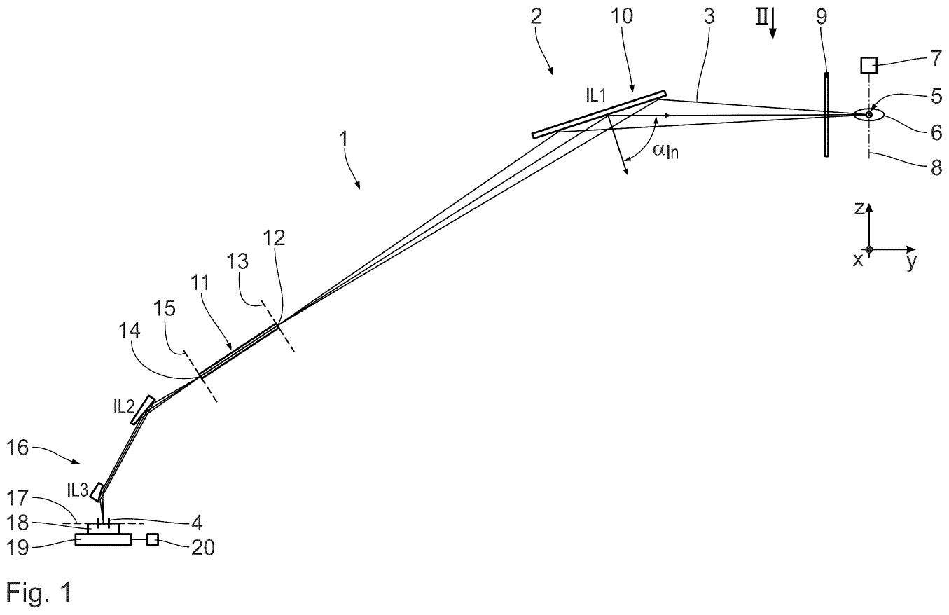

In order to facilitate positional relationships, a Cartesian xyz-coordinate system will be used hereinafter. The x-axis is perpendicular to the drawing plane of FIG. 1. The y-axis runs horizontally to the right in FIG. 1, and the z-axis runs vertically upwards in FIG. 1.

The source region 6 has an approximately ellipsoidal shape and has a greatest extent, which is also referred to as main direction of extent, parallel to the y-axis. A main emission direction of the illumination light 3 from the source region 6 runs along this main direction of extent, which is to say along a longest major axis of the ellipsoidal source region 6 in the case of an ellipsoidal approximation. A pivot drive 7 renders the source region 6 of the light source 5 pivotable about a pivot axis 8 running parallel to the z-axis. The pivot drive 7 may be embodied as a linear drive and/or as a piezo drive. The pivot drive 7 may comprise a hexapod actuator, with the result that a displacement of the source region 6 is possible in up to six degrees of freedom. Thus, the source region 6 can be displaced in up to three rotational degrees of freedom and/or in up to three translational degrees of freedom with the aid of the pivot drive 7. Typical pivot angles of the source region 6 about the pivot axis 8 are in the range of +/−15°, for example in the range of +/−2°.

Following its emission by the light source 5, the illumination light 3 initially passes through an aperture stop 9 which delimits the edge of a beam of the illumination light 3.

The aperture stop 9 can be designed to be interchangeable. For example, a stop wheel may be provided to this end, the latter storing various aperture stop embodiments which can be used alternately within the beam path of the illumination light 3. Different input apertures of the illumination light 3 may be specified by way of such an interchangeable aperture stop design.

The aperture stop 9 may be embodied to be interchangeable and/or adjustable and/or adjustable in respect of its stop edge. Different stop geometries of the aperture stop 9 can be realized and/or set as a result. By way of example, specifiable stop geometries could be round with a selectable diameter and/or elliptical with a selectable ellipse size and optionally with a selectable semi-axis ratio of the ellipses. Such a semi-axis ratio of an ellipse specifiable by way of the aperture stop 9 may be 2:1.

Following the aperture stop 9, the illumination light beam 3 is transmitted from an input coupling mirror optical unit 10 to a hollow waveguide 11 of the illumination optical unit 1.

The aperture stop 9 limits a numerical aperture of the illumination light beam 3 emitted by the source region 6 to a value of the numerical aperture ranging between 0.02 and 0.3, for example ranging between 0.02 and 0.1 or between 0.05 and 0.08. A numerical aperture, specified by the aperture stop 9, of greater than 0.1, which is to say ranging between 0.1 and 0.3, enables a greater light yield in the illumination light beam path between the source volume 6 and the illumination field 4.

An incoherent illumination setting can be used.

The aperture stop 9 can be embodied so that it follows a movement of the hexapod actuator of the pivot drive 7. In particular, the aperture stop 9 may be coupled to the hexapod actuator. As an alternative or in addition to the aperture stop 9, an aperture-limiting stop may be arranged between the hollow waveguide 11 and a downstream optical component of the illumination optical unit 1. An arrangement of such a further aperture stop in the beam path of the illumination light 3 downstream of the hollow waveguide 11 between two downstream optical components of the illumination optical unit 1 is also possible.

The input coupling mirror optical unit 10 is embodied as exactly one ellipsoid mirror IL1 and serves to image the source region 6 of the EUV light source 5 into an entrance opening 12 in an entrance plane 13 of the hollow waveguide 11. A first focus of the ellipsoid mirror IL1 is therefore located in the source region 6 and a second focus of the ellipsoid mirror IL1 is located in the entrance opening 12 or in the region of the entrance opening 12. The ellipsoid mirror IL1 is used to focus the illumination light beam 3 into the entrance opening 12 in the entrance plane 13 of the hollow waveguide 11. An entrance-side numerical aperture of the illumination light beam 3 upon entrance into the entrance opening 12 may range between 0.02 and 0.2, for example be of the order of 0.15 or be of the order of 0.05 or 0.1.

An angle of incidence din of a central chief ray of the illumination light beam 3 at the input coupling mirror IL1 ranges between 70° and 75°. In the embodiment of the illumination optical unit 1 according to FIG. 1, the ellipsoid mirror IL1 represents a mirror for grazing incidence (GI).

The entrance opening 12 and the exit opening 14 are each square or rectangular with typical dimensions ranging between 0.5 mm and 5 mm. An aspect ratio of the entrance opening 12 and an exit opening 14, of equal size, of the hollow waveguide 11 for the illumination light 3 in an exit plane 15 ranges between 0.25 and 4, for example between 0.5 and 2. Typical dimensions of the entrance opening 12 and exit opening 14 of the hollow waveguide 11 are 0.75 mm×0.75 mm, 1.0 mm×2.0 mm or 1.5 mm×2.0 mm.

An inner wall of a waveguide cavity of the hollow waveguide 11 is provided with a highly reflective coating for the illumination light 3, for example a ruthenium coating. The waveguide cavity is cuboid, in accordance with the rectangular entrance and exit openings 12, 14. The hollow waveguide 11 has a typical length in the beam direction of the illumination light 3 ranging between 10 and 500 mm, for example ranging between 20 mm and 500 mm, between 20 mm and 300 mm, or else between 20 mm and 80 mm.

Angles of incidence of the illumination light 3 on the inner wall of the waveguide cavity of the hollow waveguide 11 are greater than 60°. Illumination light 3 impinges on the inner wall with grazing incidence.

An angle α_{cr} between a longitudinal axis of the hollow waveguide 11 and the chief ray CR of the illumination light beam 3 incident into the entrance opening 12 may be 0° or may alternatively also differ from 0° and for example range between 0° and 1.5°, for example between 0.25° and 0.75° and in particular be of the order of 0.5°.

A ratio of the length of the hollow waveguide 11, which is to say the distance between the entrance plane 13 and the exit plane 15, and a typical diameter of the hollow waveguide 11, which is to say the typical size or typical diameter of the entrance opening or exit opening 12, 14, ranges between 10 and 1000 and may for example be between 10 and 500, between 30 and 500, between 30 and 300, or else between 30 and 80 or between 200 and 500.

An imaging output coupling mirror optical unit 16 situated downstream of the hollow waveguide 11 and having two mirrors IL2, IL3 images the exit opening 14, located in an exit plane 15, of the hollow waveguide 11 into the illumination field 4 in an object plane 17. This imaging may have an image-side numerical aperture ranging between 0.1 and 0.3.

The two mirrors IL2, IL3 of the output coupling mirror optical unit 16 are embodied as mirrors for grazing incidence of the illumination light 3. A mean angle of incidence α1 for the mirror 14 and α2 for the mirror 15, respectively, is greater than 60° in each case. In the case of the illumination optical unit 1, a sum α=α1+α2 of these two mean angles of incidence is approximately 150°.

In the illustrated embodiment, the output coupling mirror optical unit 16 has exactly two mirrors for grazing incidence, namely the mirrors IL2 and IL3. The above-described, optionally used aperture stop downstream of the hollow waveguide 11 may be arranged between the hollow waveguide 11 and the mirror IL2, or else between the mirrors IL2 and IL3.

The output coupling mirror optical unit 16 is embodied in the style of a Wolter telescope, namely in the style of a Type I Wolter optical unit. Such Wolter optical units are described in J. D. Mangus, J. H. Underwood “Optical Design of a Glancing Incidence X-ray Telescope,” Applied Optics, Vol. 8, 1969, page 95, and the references cited therein. In such Wolter optical units, a hyperboloid may also be used in place of a paraboloid. Such a combination of an ellipsoid mirror with a hyperboloid mirror also represents a Type I Wolter optical unit.

An exemplary embodiment of the output coupling mirror optical unit 16 is described in U.S. Pat. No. 10,042,248 B2. Alternatively, mirrors of the output coupling mirror optical unit 16 may also comprise reflection surfaces in the form of free-form surfaces.

A reticle 18 to be inspected, which is held by a reticle holder 19, is arranged in the object plane 17. The reticle holder 19 is mechanically operatively connected to a reticle displacement drive 20, by use of which the reticle 18 is displaced in an object displacement direction y during a mask inspection. In this way, a scanning displacement of the reticle 18 in the object plane 17 is rendered possible.

The illumination field 4 in the object plane 17 has a typical dimension which is less than 1 mm and which may be less than 0.5 mm. In the illustrated embodiment, the extent of the illumination field 4 is 0.5 mm in the x-direction and 0.5 mm in the y-direction.

The x/y aspect ratio of the illumination field 4 may correspond to the x/y aspect ratio of the exit opening 14.

Using a projection optical unit not illustrated in FIG. 1, the illumination field 4 is imaged into an image field in an image plane.

The image field is detected by a detection device, for example one CCD camera or a plurality of CCD cameras. Regarding details of the imaging into the image field, reference is made to U.S. Pat. No. 10,042,248 B2 and the references specified herein and in U.S. Pat. No. 10,042,248 B2.

An inspection of a structure on the reticle 18, for example, is possible by use of the mask inspection system.

An imaging factor β₁ of the input coupling mirror optical unit 10 may range between 0.1 and 50, which is to say its action may vary from a reduction by a factor of 10 to a magnification of a factor of 50. An imaging factor β₂ of the output coupling mirror optical unit 16 may range between 0.02 and 10, which is to say its action in turn may vary from a reduction by a factor of 50 to a magnification of a factor of 10. In the case of the illumination optical unit 1, a product of the two imaging factors β₁, β₂ may range between 0.25 and 10.

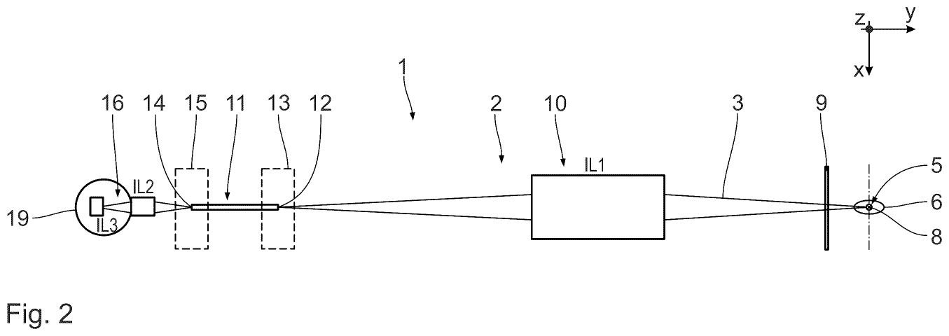

FIG. 2 shows a plan view of the optical system 2 with the illumination optical unit 1. The entrance plane 13 is highlighted in FIG. 2.

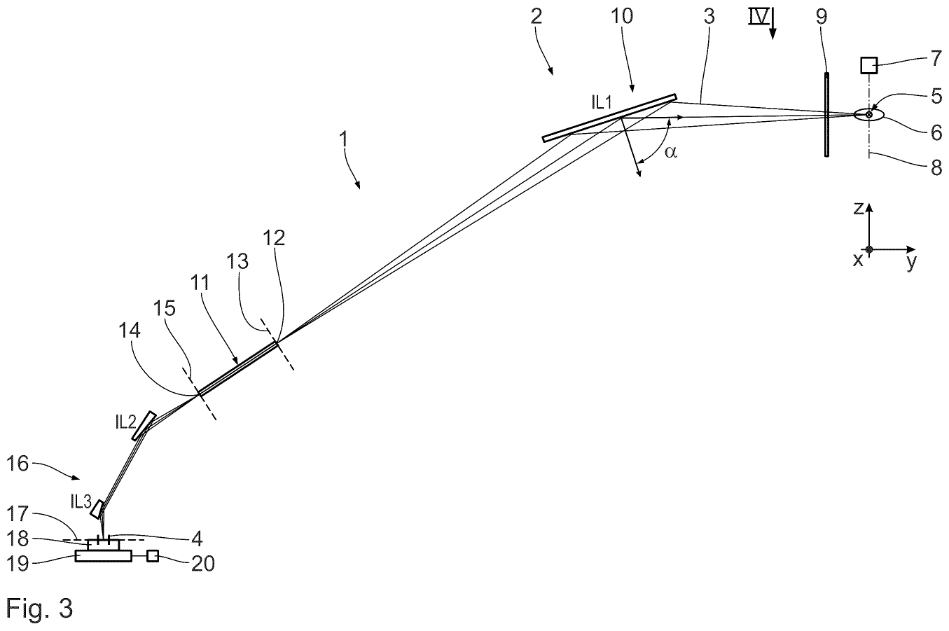

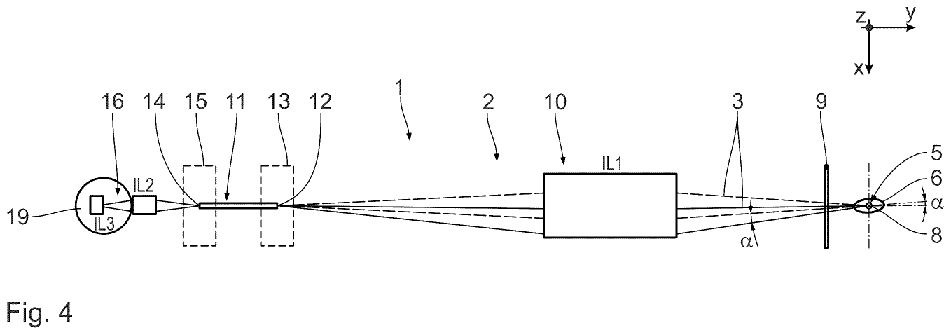

To vary the chief ray entrance angle α_{CR} of the illumination light beam 3 at the entrance opening 12, which is to say the angle of the chief ray CR of the illumination light beam 3 with respect to the longitudinal axis of the hollow waveguide 11, the source region 6 of the light source 5 is pivoted about the pivot axis 8 with the aid of the pivot drive 7. The effect of this pivot is shown by a comparison of FIGS. 1 and 2, which represent the situation prior to the pivot, with FIGS. 3 and 4, which represent the situation after the pivot. The effect of a corresponding tilt of the chief ray direction through an angle α in the xy-plane in comparison with the original chief ray direction according to FIG. 2 can be gathered from the plan view according to FIG. 4 in particular. As a result of the imaging effect of the mirror IL1, this tilt is converted into a corresponding change in chief ray angle upon entry of the chief ray of the illumination light beam 3 into the entrance opening 12 in the entrance plane 13.

FIG. 5 schematically shows the effect of a non-zero chief ray angle α_{CR} of a chief ray CR of the illumination light beam 3 entering the entrance opening 12 of the hollow waveguide 11, with respect to the longitudinal axis L of the hollow waveguide 11. On account of the angle α_{CR}, both the chief ray CR and the other individual rays of the illumination light beam 3 are reflected at least once at the inner wall of the waveguide cavity of the hollow waveguide 11. As a consequence, an angle distribution within the illumination light beam post exit from the exit opening 14 is influenced. This exit angle distribution is indicated schematically in FIG. 5 on the basis of a multiplicity of individual rays 21 of the illumination light beam 3.

To specify a monopole-type illumination angle distribution, the incoming illumination light 3 shines with a chief ray running along the longitudinal axis L (α_{CR}=0). In this case, the variant in which an illumination angle distribution of the incident illumination light 3 is symmetric about the longitudinal axis L is preferred. The illumination light beam 3 emerging from the hollow waveguide 11 then has, in turn, a corresponding illumination angle distribution which is centered about the longitudinal axis L and which corresponds in terms of its angle variation to the angle distribution of the incident illumination light beam 3. On account of the reflections at the inner wall of the hollow waveguide 11, the illumination angles of the emerging illumination light beam 3 are redistributed within the illumination angle variation of the incident illumination light beam 3, with no new illumination angles occurring however. This redistribution may lead to a homogenization of an intensity distribution within the illumination angles of the illumination light beam 3.

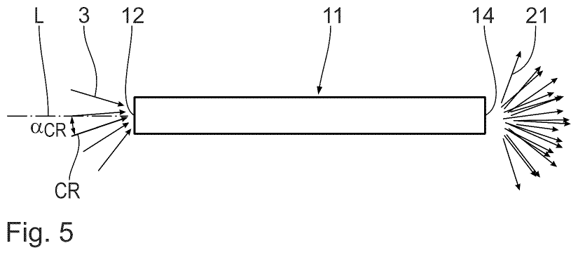

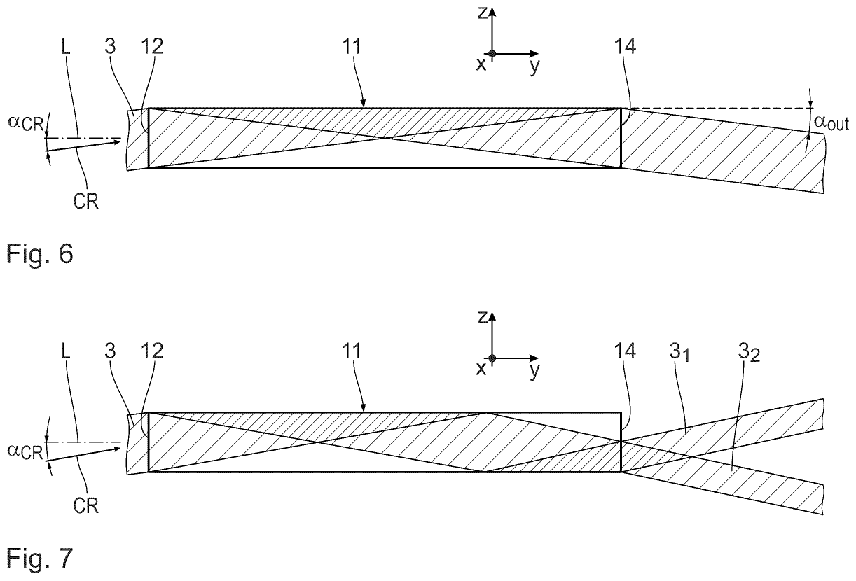

FIGS. 6 and 7 below show reflection conditions in the hollow waveguide 11 for the case of a single incident illumination angle. In the cases relevant in practice, the incident light 3 does not have only one incident illumination angle but has many incident illumination angles.

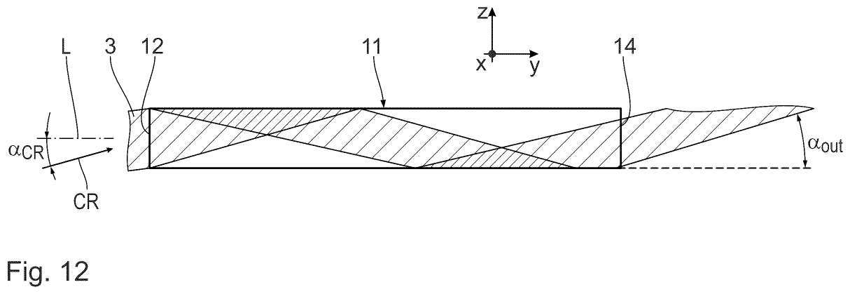

FIG. 6 illustrates a variant of an “odd number of reflections” reflection situation in the case of the idealized version of precisely one non-zero chief ray angle α_{CR} and in which there is exactly one exit angle αₒᵤₜ of the illumination light beam 3 exiting from the exit opening 14 following the exit from the exit opening 14. In this case, the angle of incidence α_{CR} of the chief ray at the entrance opening 12 is exclusively in the yz-plane, which is to say in the plane of the drawing of FIG. 6. In the projection onto the xy-plane of FIG. 6, the incident chief ray of the illumination light beam 3 runs parallel to the longitudinal axis L of the hollow waveguide 11. In FIG. 6, and in corresponding FIGS. 7 and 12 yet to be described hereinafter, the hollow waveguide 11 has not been depicted true to scale, with the result that the angle of incidence α_{CR} is also depicted in exaggerated fashion in each case. The illumination angle distribution according to FIG. 6 is realized by an odd number of reflections of the illumination light beam 3 at the inner wall of the waveguide cavity of the hollow waveguide 11. In this case, all individual rays of the illumination light beam 3 experience an odd number of reflections. This number of reflections is regularly greater than 1, with the result that FIG. 6 should be understood schematically in this respect. In fact, the odd number of reflections may be very much larger and for example be of the order of 50 or else be of the order of even larger odd numbers.

FIG. 7 shows a further idealized angle of incident radiation and reflection configuration, in which the illumination light beam 3 is radiated-in at a different angle of incidence α_{CR}, for example at a larger one, in comparison with the configuration according to FIG. 6. Following the first reflection of the entire illumination light beam 3 at the inner wall of the hollow waveguide 11, half of an entire cross section of the illumination light beam 3 is reflected a second time at the opposite inner wall of the hollow waveguide 11 and exits from the exit opening 14 as illumination light component beam 31. The remaining portion of the incident illumination light beam 3 is not reflected again following the first reflection and exits the exit opening 14 as illumination light component beam 32. Thus, there is in part an odd number of reflections and in part an even number of reflections of the illumination light beam at the inner wall of the waveguide cavity of the hollow waveguide 11, accordingly leading to a dipole-type illumination angle distribution. In accordance with what was explained above in the context of FIG. 6, the actual number of reflections is regularly greater than the number of reflections in the schematic illustration according to FIG. 7.

FIG. 12 shows a further idealized entrance and reflection configuration, in which the angle of incidence α_{CR} of the chief ray CR of the illumination light beam 3 with respect to the longitudinal axis L of the hollow waveguide 11 was increased yet again in the yz-plane in comparison with FIG. 7. In turn, the entire illumination light beam 3 now experiences precisely two reflections at the opposing inner walls of the hollow waveguide 11, with the result that there is in turn precisely one illumination emergence angle αₒᵤₜ of the entire illumination light beam 3 following the exit from the exit opening 14 in the idealized illustrated case of FIG. 12.

To the extent that a plurality or multiplicity of further illumination angles of the incident illumination light beam 3 are present around a non-zero chief ray angle of incidence α_{CR}, there is a superposition of the reflection configurations according to FIGS. 6, 7 and 12, and this can be used to generate dipole and multi-pole illumination angle distributions of the emerging illumination light beam 3.

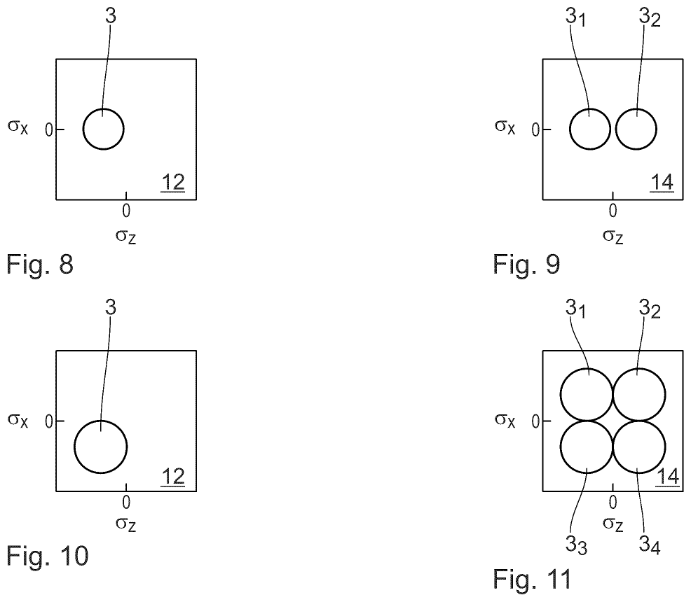

FIG. 8 shows a pupil representation (pupil coordinates σₓ, σ_{z} corresponding to the spatial coordinates x and z) of the illumination angle distribution upon entrance of the illumination light beam 3 into the entrance opening 12. A bounded continuum of illumination angles is present at this entrance. This illumination angle continuum is off centered in relation to the pupil coordinates, with the result that α_{CR}≠0 applies. If the incident illumination angle continuum depicted in FIG. 8 were arranged centrally at σₓ=0, σ_{z}=0, then the case of the generation of a monopole-like illumination angle distribution would be present, as explained above. The case α_{CR}≠0 is present in the actually depicted variant.

FIG. 9 shows the situation according to FIG. 7 upon exit of the illumination light beam 3 from the exit opening 14. There now is a bounded, dipole-like continuum of illumination angles present, which is to say a dipole-like illumination angle distribution. To the extent that an even number of reflections is present, the emerging illumination light beam has an illumination angle distribution corresponding to the illumination light component beam 31. In the case of an odd number of reflections, the illumination angle distribution corresponding to the illumination light component beam 32 is present. Thus, overall and as illustrated in FIG. 9, this results in an illumination angle distribution of the emerging illumination light 3 in the form of a dipole.

FIGS. 10 and 11 show an angle of incident radiation and reflection configuration, in which there is a non-zero angle of incident radiation α_{CR} of the chief ray CR of the illumination light beam 3 with respect to the longitudinal axis L of the hollow waveguide 11, both in the projection on the yz-plane and in the projection on the xy-plane. This results in splits of cross-sectional components of the incident illumination light beam 3 both in the yz-plane, for example as illustrated in FIG. 7, and in the xy-plane perpendicular thereto.

FIG. 10 shows this angle of incidence situation in a pupil representation corresponding to that of FIG. 8; in the case of FIG. 10, the chief ray 3 incident into the entrance opening 12 is incident into the entrance opening 12 at a non-zero angle with respect to the longitudinal axis L of the hollow waveguide 11, both in relation to the yz-plane and in relation to the xy-plane. Following the exit from the exit opening 14 with splitting into in each case two illumination light component beams taking place in both the yz and xy plane, which is to say with splitting into a total of four illumination light component beams 31, 32, 33 and 34 taking place, what emerges is a quadrupole-like illumination angle distribution of the illumination light beam 3, as illustrated in the pupil representation according to FIG. 11.

As a result of tilting the source region 6 about the pivot axis 8 and about a further pivot axis, in particular a further pivot axis arranged perpendicular thereto, it is thus possible, proceeding from the monopole-like illumination angle distribution at α_{CR}=0, to generate both a dipole-like illumination angle distribution according to FIGS. 6, 7, 12 and 9 and a quadrupole-like illumination angle distribution according to FIG. 11, each of which can then be used to illuminate the illumination field 4.

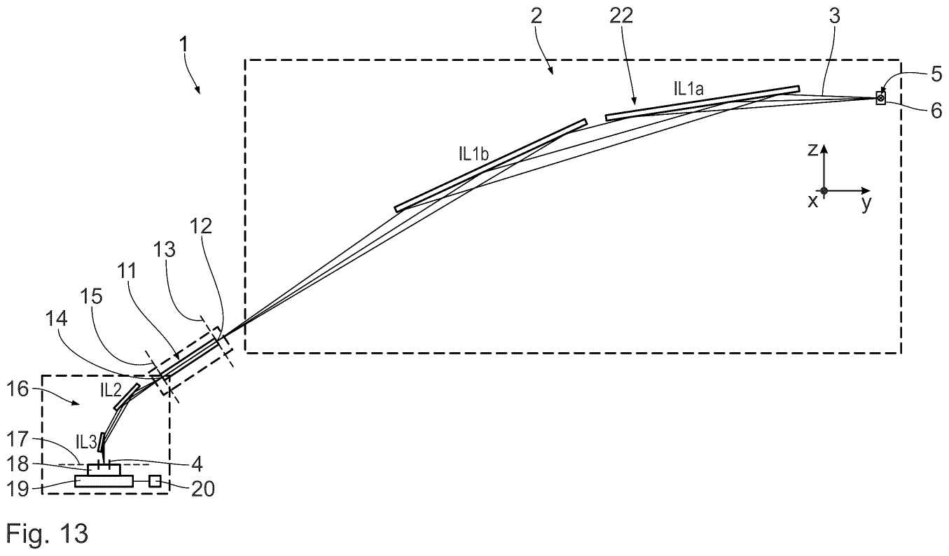

An alternative input coupling mirror optical unit 22 which can be used instead of the input coupling mirror optical unit 10 is explained hereinafter on the basis of FIG. 13. Components and functions which have already been explained above with reference to FIGS. 1 to 12 bear the same reference signs and will not be discussed again in detail.

The input coupling mirror optical unit 22 according to FIG. 13 comprises precisely two mirrors IL1a, IL1b which jointly form a Type I Wolter optical unit, as has already been explained above in the context of the output coupling mirror optical unit 16. The two mirrors IL1a, IL1b are embodied as an ellipsoid mirror and as a hyperboloid mirror, for example. What applies to all mirrors IL1a, IL1b and to the mirrors IL2, IL3 in the case of the illumination optical unit 1 according to FIG. 13 is that the angles of incidence of the illumination light beam there are significantly greater than 60° in each case.

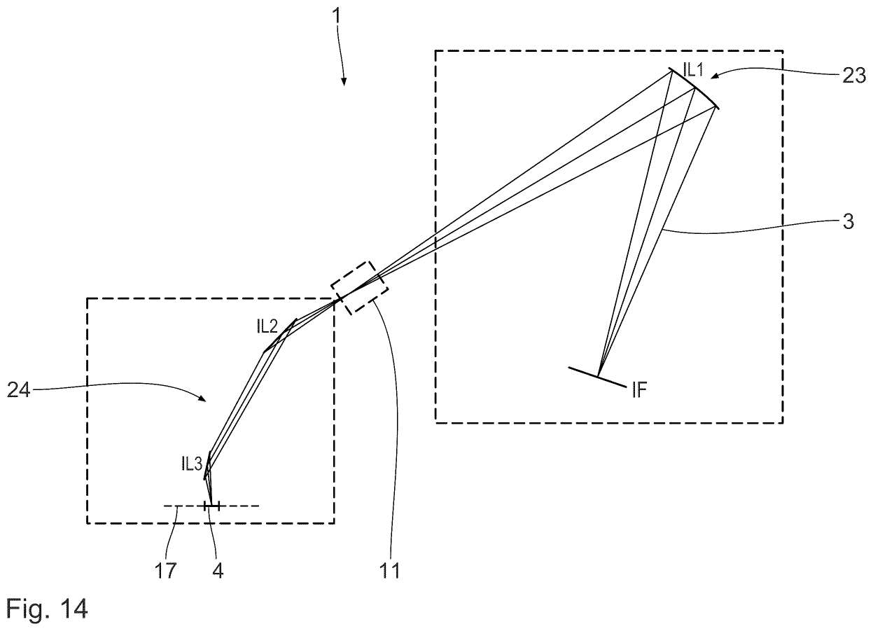

FIG. 14 shows an alternative illumination optical unit 1 for the mask inspection system, which can be used in place of the illumination optical units described above. Components and functions which have already been explained above with reference to FIGS. 1 to 13 bear the same reference signs and will not be discussed again in detail. In FIG. 14, a beam path of the illumination light 3 is illustrated starting from an intermediate focus IF, into which the source region 6 is transmitted with the aid of an appropriate collector optical unit.

An input coupling mirror optical unit 23 of the illumination optical unit 1 according to FIG. 14 has precisely one mirror IL1, which is designed as an NI mirror and on which illumination light 3 impinges with an angle of incidence of less than 30°. The mirror IL1 has a coating made of alternating molybdenum/silicon bilayers, which is highly reflective to the illumination light 3.

An output coupling mirror optical unit 24 of the illumination optical unit 1 according to FIG. 14, which can be used in place of the output coupling mirror optical unit 16, comprises two mirrors IL2 and IL3 on which, as GI mirrors, illumination light 3 impinges in turn with grazing incidence. An angle of incidence of a central chief ray of the illumination light 3 at the object plane 17 of the object field 4 is slightly larger in the case of the output coupling mirror optical unit 24 than in the case of the output coupling mirror optical unit 16. This angle of incidence is also less than 10° in the case of the output coupling mirror optical unit 24.

The two mirrors IL2, IL3 of the output coupling mirror optical unit 24 also have a ruthenium coating, which is embodied as a highly reflective coating for the illumination light 3.

An NI mirror of the illumination optical unit, in particular as a constituent part of the input coupling mirror optical unit such as the mirror IL1, enables a significant suppression of wavelength components carried along with the illumination light 3 but which differ from a used light wavelength of the illumination light. A coating on the NI mirror which reflects used light wavelengths to a great extent can consequently serve as a bandpass filter for the used light wavelengths and can reflectively block other wavelengths, for example a pump light wavelength for producing a source plasma in the source volume 6.

A corresponding reflectivity coating may be realized by alternating bilayers made of molybdenum and silicon in the form of a multilayer coating. Such a coating can pass a used light wavelength in the range from 5 nm to 30 nm with a bandwidth of 2 nm, for example, and a maximum reflectivity of 60%, for example. In the surroundings around a specified used light wavelength range, a suppression of such a multilayer coating may be better than 1×10⁻³, may be better than 1×10⁴ and may also be better than 1×10⁻⁵.

The two mirrors IL2, IL3 of the output coupling mirror optical unit 24 may have reflection surfaces which can be described as free-form surfaces. For example, such free-form surfaces can be parameterized as follows:

$$z ( x , y ) = \frac{{x}^{2} + {y}^{2}}{R ( 1 + \sqrt{1 - \frac{( 1 + k ) ( {x}^{2} + {y}^{2} )}{{R}^{2}}} )} + {\sum }_{i , k} {a}_{i k} {x}^{i} {y}^{k}$$

Here, z is the respective sag of the reflection surface to be described, x and y are Cartesian coordinates of the respectively used surface reference coordinate system, R is a radius of curvature corresponding to a usual asphere equation and k is a conic constant corresponding to a usual asphere equation. The free-form surfaces equation is complemented by a polynomial expansion term in powers of x and y. Each exponent pair i, k of this expansion in powers of x and y has an assigned coefficient aᵢₖ.

Using an optimization algorithm, it is possible proceeding from a raw asphere shape to optimize the polynomial coefficients aᵢₖ, the radii R, the conic constants k and the basic positions of the mirrors IL2 and IL3, in particular the distances thereof from upstream and downstream components of the output coupling mirror optical unit 24, in such a way that residual aberrations are minimized during the adaptation of an illumination intensity distribution and/or an illumination angle distribution of the illumination light 3 over the illumination field 4 to requirements of a downstream imaging optical unit for imaging the object field 4 into an image field of the mask inspection system.

In accordance with the pivotability of the light source 5, the hollow waveguide 11 may also be embodied to be pivotable about at least one pivot axis with the aid of a corresponding pivot actuator. This hollow waveguide pivot axis may be located in the entrance plane 13 of the entrance opening 12. It is possible to use pivot drive designs which were explained above with reference to the pivot drive 7 of the light source 5.

What is claimed is:

1. An illumination optical unit for a mask inspection system for use with EUV illumination light,
comprising a hollow waveguide serving to guide the illumination light and having an entrance opening for the illumination light, the said entrance opening specifying an entrance plane of the hollow waveguide, and having an exit opening for the illumination light, the said exit opening specifying an exit plane of the hollow waveguide,
comprising an input coupling mirror optical unit disposed upstream of the hollow waveguide in the beam path of the illumination light and having at least one mirror for imaging a source region of an EUV light source into the entrance opening of the hollow waveguide, and
comprising an output coupling mirror optical unit for imaging the exit opening of the hollow waveguide into an illumination field.

2. The illumination optical unit of claim 1, wherein the input coupling mirror optical unit is embodied as an ellipsoid mirror.

3. The illumination optical unit of claim 1, comprising an arrangement such that an angle between a normal of the entrance plane of the entrance opening and an incident chief ray of a beam of the illumination light ranges between 0° and 5°.

4. The illumination optical unit of claim 1, wherein an angle of incidence of a chief ray of a beam of the illumination light on the at least one mirror of the input coupling mirror optical unit ranges between 70° and 89.9°.

5. The illumination optical unit of claim 1, wherein the input coupling mirror optical unit is embodied as a combination of an ellipsoid mirror and a hyperboloid mirror.

6. The illumination optical unit of claim 1, wherein the entrance opening of the hollow waveguide has a rectangular embodiment.

7. The illumination optical unit of claim 1, wherein at least one of the components of the illumination optical unit is embodied to be pivotable about at least one pivot axis.

8. The illumination optical unit of claim 7, wherein the pivotable component of the illumination optical unit is the hollow waveguide.

9. An optical system comprising an illumination optical unit according to claim 1 and comprising an EUV light source for the illumination light.

10. The optical system of claim 9, wherein the light source is embodied to be pivotable about at least one axis which runs through a source region of the light source.

11. A mask inspection system
comprising an optical system according to claim 9,
comprising a projection optical unit for imaging the illumination field into an image field and
comprising a detection device for detecting illumination light incident on the image field.

12. The mask inspection system of claim 11, wherein the light source is embodied to be pivotable about at least one axis which runs through a source region of the light source.

13. The mask inspection system of claim 11, wherein the input coupling mirror optical unit is embodied as an ellipsoid mirror.

14. The mask inspection system of claim 11, wherein the illumination optical unit comprises an arrangement such that an angle between a normal of the entrance plane of the entrance opening and an incident chief ray of a beam of the illumination light ranges between 0° and 5°.

15. The mask inspection system of claim 11, wherein an angle of incidence of a chief ray of a beam of the illumination light on the at least one mirror of the input coupling mirror optical unit ranges between 70° and 89.9°.

16. The mask inspection system of claim 11, wherein the input coupling mirror optical unit is embodied as a combination of an ellipsoid mirror and a hyperboloid mirror.

17. The illumination optical unit of claim 2, comprising an arrangement such that an angle between a normal of the entrance plane of the entrance opening and an incident chief ray of a beam of the illumination light ranges between 0° and 5°.

18. The illumination optical unit of claim 2, wherein an angle of incidence of a chief ray of a beam of the illumination light on the at least one mirror of the input coupling mirror optical unit ranges between 70° and 89.9°.

19. The illumination optical unit of claim 2, wherein the input coupling mirror optical unit is embodied as a combination of an ellipsoid mirror and a hyperboloid mirror.

20. The illumination optical unit of claim 2, wherein the entrance opening of the hollow waveguide has a rectangular embodiment.
